(19) United States
(12) Patent Application Publication
(10) Pub. No.: US 2020/0376538 A1
(43) Pub. Date: Dec. 3, 2020

(54) MANUFACTURING METHOD OF ROLL BOND PLATE EVAPORATOR STRUCTURE

(71) Applicant: ASIA VITAL COMPONENTS (CHINA) CO., LTD., Shenzhen (CN)

(72) Inventors: Pai-Ling Kao, Shenzhen (CN); Dan-Jun Chen, Shenzhen (CN); Guo-Hui Li, Shenzhen (CN); Fu-Ming Zhong, Shenzhen (CN)

(21) Appl. No.: 16/423,129

(22) Filed: May 27, 2019

(51) Int. Cl. B21D 53/04; H05K 7/20; B23K 26/24; F28F 3/12; B08B 9/032

(52) U.S. Cl. CPC B21D 53/04; H05K 7/20309; H05K 7/2039; B08B 2209/032; F28F 3/12; B08B 9/032; F28F 2275/067; B23K 26/24

(57) ABSTRACT

A manufacturing method of a roll bond plate evaporator structure is disclosed. The roll bond plate evaporator structure includes a heat dissipation member, at least one inlet and at least one outlet. The heat dissipation member is composed of a first plate body and a second plate body, which are correspondingly mated with each other. The first and second plate bodies together define a flow way. A working fluid is filled in the flow way. The inlet is formed at one end of the heat dissipation member in communication with the flow way and the outlet is formed at the other end of the heat dissipation member in communication with the flow way.

### BACKGROUND OF THE INVENTION

### 1. Field of the Invention

The present invention relates generally to a manufacturing method of a roll bond plate evaporator structure, and more particularly to a manufacturing method of a roll bond plate evaporator structure which can enhance the sealability of the inlet and the outlet and greatly reduce the possibility of leakage of the working fluid.

### 2. Description of the Related Art

The operation performances of the current mobile devices, personal computers, servers, communication chassis and other systems or devices have become higher and higher. As a result, the heat generated by the internal operation units of these electronic devices has become higher and higher. Therefore, it is necessary to use heat dissipation units to dissipate the heat. Most of the manufacturers employ the heat sink (composed of multiple radiating fins), heat pipe, vapor chamber and other heat dissipation components in cooperation with cooling fans to dissipate the heat. In case of large-area heat dissipation, a heat dissipation device (heat sink) and cooling fan are used to forcedly dissipate the heat.

In the current market, some manufacturers have employed roll bond plate evaporator to replace the conventional radiating fin. During the manufacturing process of the roll bond plate evaporator, in both the roll bond process and the welding process, the roll bond plate evaporator is brushed with graphite powder and sprayed with welding flux to facilitate the successive manufacturing step. As a result, impurities will exist in the flow way of the roll bond plate evaporator and is hard to clean up. When vacuuming the flow way, the impurities in the flow way may be also sucked out to accumulate in the vacuuming device. This may lead to damage of the vacuuming device and shorten the lifetime of the vacuuming device. Moreover, when filling a working fluid into the roll bond plate evaporator and sealing the opening of the roll bond plate evaporator, due to the existence of the impurities in the flow way, it is uneasy to tightly seal the opening in the welding process. Therefore, the working fluid is apt to leak out. This greatly increases the ratio of defective products.

In conclusion, the conventional roll bond plate evaporator has the following shortcomings:

1. It is uneasy to tightly seal the opening.

2. The working fluid is apt to leak out.

3. The vacuuming device is quite easy to damage.

It is therefore tried by the applicant to provide a roll bond plate evaporator structure and a manufacturing method thereof to solve the problems existing in the conventional roll bond plate evaporator structure.

### SUMMARY OF THE INVENTION

It is therefore a primary object of the present invention to provide a roll bond plate evaporator structure, which can greatly enhance the sealability of the inlet and the outlet.

It is a further object of the present invention to provide the above roll bond plate evaporator structure, which can greatly lower the possibility of leakage of the working fluid.

It is still a further object of the present invention to provide the above roll bond plate evaporator structure, which can greatly increase the ratio of good products.

It is still a further object of the present invention to provide the above roll bond plate evaporator structure, which can avoid damage of the vacuuming device.

It is still a further object of the present invention to provide a manufacturing method of a roll bond plate evaporator, which can greatly enhance the sealability of the inlet and the outlet.

It is still a further object of the present invention to provide the above manufacturing method of the roll bond plate evaporator, which can greatly lower the possibility of leakage of the working fluid.

It is still a further object of the present invention to provide the above manufacturing method of the roll bond plate evaporator, which can greatly increase the ratio of good products.

It is still a further object of the present invention to provide the above manufacturing method of the roll bond plate evaporator, which can avoid damage of the vacuuming device.

To achieve the above and other objects, the roll bond plate evaporator structure of the present invention includes a heat dissipation member, at least one inlet and at least one outlet. The heat dissipation member is composed of a first plate body and a second plate body, which are correspondingly mated with each other. The first and second plate bodies together define a flow way. A working fluid is filled in the flow way. The inlet is formed at one end of the heat dissipation member in communication with the flow way and the outlet is formed at the other end of the heat dissipation member in communication with the flow way.

To achieve the above and other objects, the manufacturing method of the roll bond plate evaporator of the present invention includes steps of:

providing a heat dissipation member having at least one inlet and at least one outlet and formed with an internal flow way in communication with the inlet and the outlet;

providing a cleaning liquid to fill into the heat dissipation member from the inlet and flow from the inlet through the flow way to the outlet and discharge out of the heat dissipation member;

providing a sealing device to seal the outlet; and

providing a vacuuming device to vacuum the flow way and filling a working fluid into the flow way from the inlet and then sealing the inlet.

According to the manufacturing method of the present invention, the flow way is cleaned up with the cleaning liquid and washed with the liquid so that no impurity exists in the flow way. Therefore, in the manufacturing process of the heat dissipation member, when the vacuuming device is used to vacuum the flow way, no impurity remains in the flow way to cause damage of the vacuuming device. Also, by means of the washing of the cleaning liquid and the liquid, the inlet and the outlet are cleaned up and the impurities are removed to the outer side of the heat dissipation member. Accordingly, when welding and sealing the inlet and the outlet, the sealability of the inlet and the outlet is greatly enhanced. This greatly lowers the possibility of leakage of the working fluid and greatly increases the ratio of good products.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the roll bond plate evaporator structure of the present invention;

FIG. 2 is a perspective assembled view of the first embodiment of the roll bond plate evaporator structure of the present invention;

FIG. 3 is a sectional view of the first embodiment of the roll bond plate evaporator structure of the present invention;

FIG. 4 is a sectional view of a second embodiment of the roll bond plate evaporator structure of the present invention;

FIG. 5 is a flow chart of a first embodiment of the manufacturing method of the roll bond plate evaporator structure of the present invention;

FIG. 6 is a flow chart of a second embodiment of the manufacturing method of the roll bond plate evaporator structure of the present invention;

FIG. 7 is a flow chart of a third embodiment of the manufacturing method of the roll bond plate evaporator structure of the present invention; and

FIG. 8 is a flow chart of a fourth embodiment of the manufacturing method of the roll bond plate evaporator structure of the present invention.

### DETAILED DESCRIPTION OF THE PREFERRED EMBODIMENTS

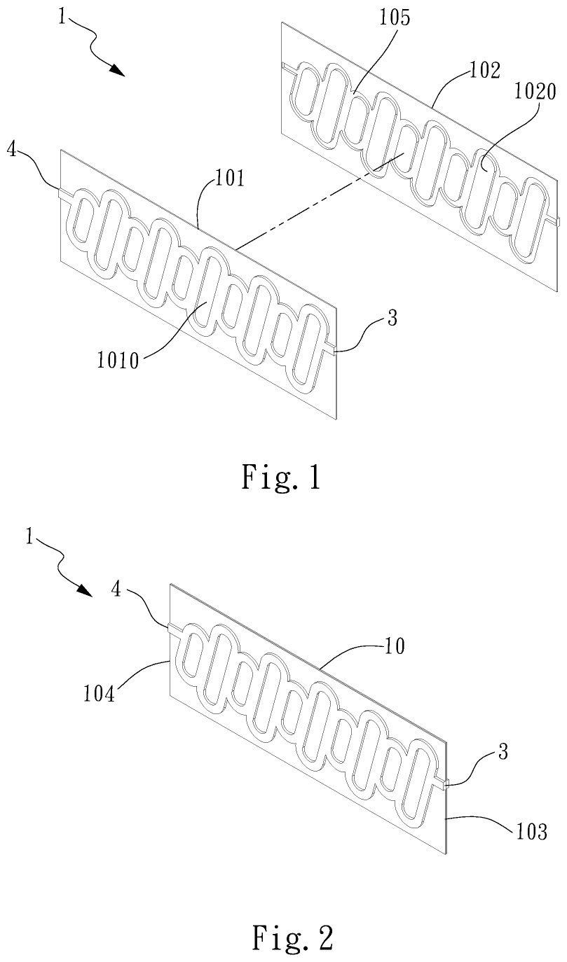

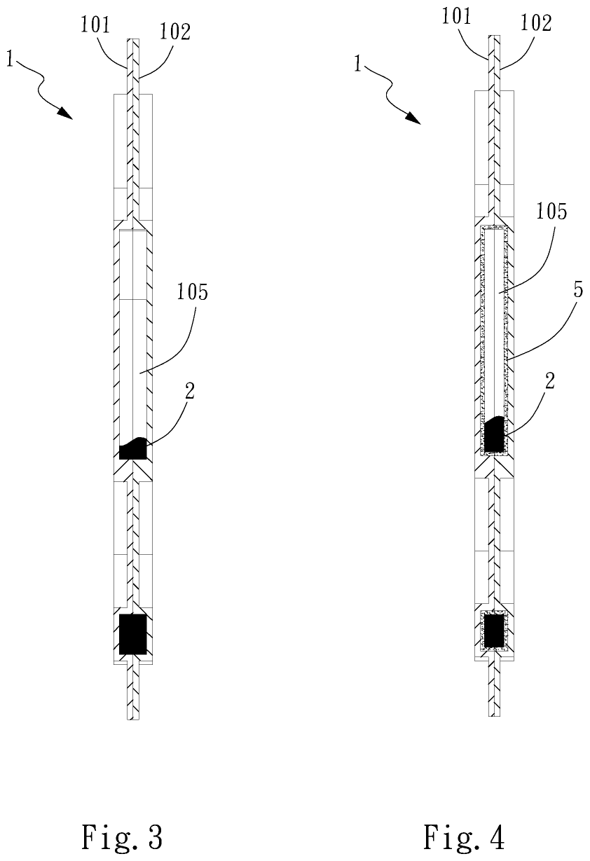

Please refer to FIGS. 1 to 3. FIG. 1 is a perspective exploded view of a first embodiment of the roll bond plate evaporator structure of the present invention. FIG. 2 is a perspective assembled view of the first embodiment of the roll bond plate evaporator structure of the present invention. FIG. 3 is a sectional view of the first embodiment of the roll bond plate evaporator structure of the present invention. As shown in the drawings, the roll bond plate evaporator structure 1 of the present invention includes a heat dissipation member 10, at least one inlet 3 and at least one outlet 4. The heat dissipation member 10 is composed of a first plate body 101 and a second plate body 102, which are correspondingly mated with each other. The heat dissipation member 10 has a first end 103 and a second end 104. The first plate body 101 has multiple first recesses 1010 and the second plate body 102 has multiple second recesses 1020. The first and second plate bodies 101, 102 are correspondingly mated with each other with the first and second recesses 1010, 1020 correspondingly attached to each other, whereby the outer peripheries of the first and second recesses 1010, 1020 are connected with each other to form a flow way 105. A working fluid 2 is filled in the flow way 105. The inlet 3 is formed at the first end 103 of the heat dissipation member 10, while the outlet 4 is formed at the second end 104 of the heat dissipation member 10. The inlet 3, the outlet 4 and the flow way 105 communicate with each other.

Please further refer to FIG. 4, which is a sectional view of a second embodiment of the roll bond plate evaporator structure of the present invention. In this embodiment, at least one capillary structure 5 is disposed on the inner wall of the flow way 105. The capillary structure 5 is selected from a group consisting of mesh body, fiber body, porous structure body, channeled body and whisker and any combination thereof. The capillary structure 5 serves to enhance the vapor-liquid circulation of the working fluid 2 in the heat dissipation member 10.

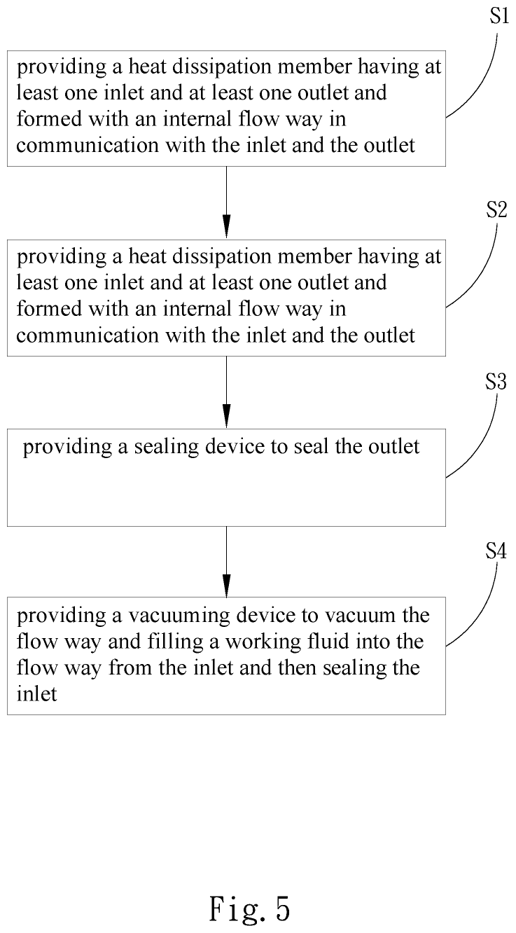

Please now refer to FIG. 5, which is a flow chart of a first embodiment of the manufacturing method of the roll bond plate evaporator structure of the present invention. According to the first embodiment, the manufacturing method of the roll bond plate evaporator structure of the present invention includes steps of:

S1. providing a heat dissipation member (sheet, plate) having at least one inlet and at least one outlet and formed with an internal flow way in communication with the inlet and the outlet, a heat dissipation member 10 being first provided, the heat dissipation member 10 being composed of a first plate body 101 and a second plate body 102, which are correspondingly mated with each other by means of welding, punching, engagement or other connection method, after the first and second plate bodies 101, 102 are correspondingly mated with each other, at least one inlet 3 being formed at one end of the heat dissipation member 10 and a second end being formed at the other end of the heat dissipation member 10, the first and second plate bodies 101, 102 together defining a flow way 105, the inlet 3, the flow way 105 and the outlet 4 being in communication with each other, the heat dissipation member 10 being a roll bond plate evaporator;

S2. providing a cleaning liquid to fill into the heat dissipation member from the inlet and flow from the inlet through the flow way to the outlet and discharge out of the heat dissipation member, a cleaning liquid in a cleaning device being filled from the inlet 3 of the heat dissipation member 10 into the flow way 105 of the heat dissipation member 10, the cleaning liquid first flowing from the inlet 3 through the flow way 105 and then flowing out of the outlet 4 to discharge from the heat dissipation member 10, in this step, the cleaning liquid being continuously circulated to clean up the interior of the heat dissipation member 10 so as to remove the impurities in the flow way 105, the cleaning liquid being a chemical agent;

S3. providing a sealing device to seal the outlet, a sealing device being provided to seal the outlet, the sealing device being a welding device or any other equivalent device, after cleaned up, the outlet 4 of the heat dissipation member 10 being first sealed by the welding device by means of argon arc welding, flame welding, high-frequency welding, laser welding or seam welding; and

S4. providing a vacuuming device to vacuum the flow way and filling a working fluid into the flow way from the inlet and then sealing the inlet, a vacuuming device being positioned at the inlet 3 of the heat dissipation member 10 to vacuum the flow way 105, a working fluid 2 being then filled from the inlet 3 into the flow way 105 and then the inlet 3 being sealed to complete the manufacturing process of the roll bond plate evaporator structure 1. The vacuuming device can be a vacuuming pump or any other equivalent device.

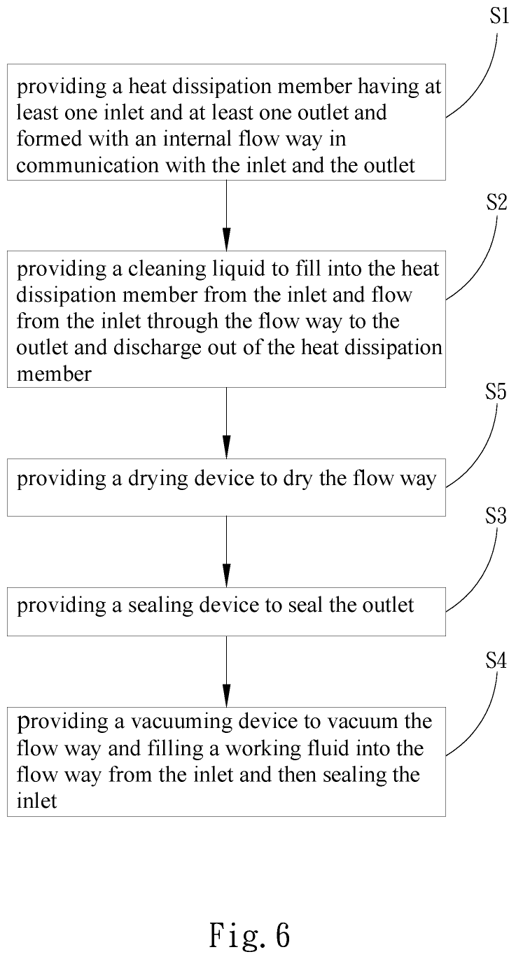

Please now refer to FIG. 6, which is a flow chart of a second embodiment of the manufacturing method of the roll bond plate evaporator structure of the present invention. The second embodiment is different from the first embodiment in that the second embodiment further includes a step S5 of providing a drying device to dry the flow way after the step S2 of providing a cleaning liquid to fill into the heat dissipation member from the inlet and flow from the inlet through the flow way to the outlet and discharge out of the heat dissipation member. After the flow way 105 is cleaned up with the cleaning liquid, a drying device is used to dry the flow way 105, whereby the interior of the flow way 105 can be quickly dried to speed the successive manufacturing procedure.

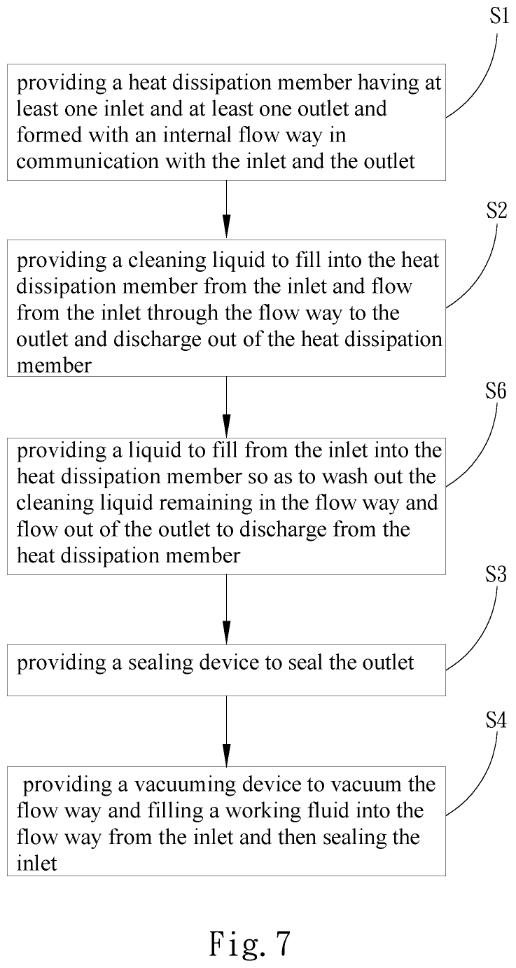

Please now refer to FIG. 7, which is a flow chart of a third embodiment of the manufacturing method of the roll bond plate evaporator structure of the present invention. The third embodiment is different from the first embodiment in that the third embodiment further includes a step S6 of providing a liquid to fill from the inlet into the heat dissipation member so as to wash out the cleaning liquid remaining in the flow way and flow out of the outlet to discharge from the heat dissipation member after the step S2 of providing a cleaning liquid to fill into the heat dissipation member from the inlet and flow from the inlet through the flow way to the outlet and discharge out of the heat dissipation member.

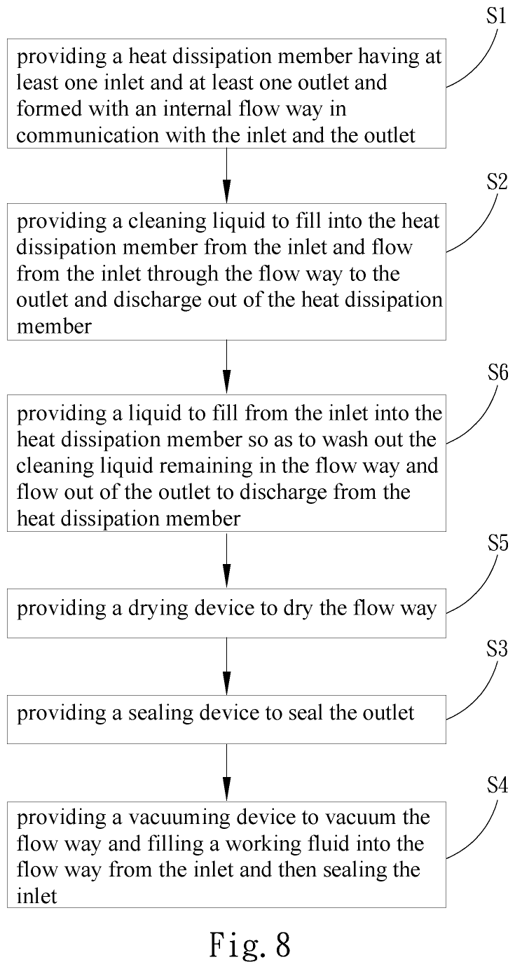

After the flow way 105 is cleaned up with the cleaning liquid, a liquid is further used to wash and clean up the flow way 105 again. That is, after the flow way 105 is cleaned up with the cleaning liquid, the liquid, (which can be pure water) is filled from the inlet 3 of the heat dissipation member 10 into the internal flow way 105 of the heat dissipation member 10 so as to totally wash out the cleaning liquid remaining in the flow way 105. Then the liquid flows out of the outlet 4 to discharge from the heat dissipation member 10. Certainly, after this step is completed, the aforesaid step S5 of providing a drying device to dry the flow way can be further performed (as shown in FIG. 8, which is a flow chart of a fourth embodiment of the manufacturing method of the roll bond plate evaporator structure of the present invention). The successive manufacturing procedure is identical to the flow chart of the second embodiment and thus will not be redundantly described hereinafter.

According to the manufacturing method of the present invention, the flow way 105 is cleaned up with the cleaning liquid and washed with the liquid so that no impurity exists in the flow way 105. Therefore, in the manufacturing process of the heat dissipation member 10, when the vacuuming device is used to vacuum the flow way 105, no impurity remains in the flow way 105 to cause damage of the vacuuming device. Also, by means of the washing of the cleaning liquid and the liquid, the inlet 3 and the outlet 4 are cleaned up and the impurities are removed to the outer side of the heat dissipation member 10. Accordingly, when welding and sealing the inlet 3 and the outlet 4, the sealability of the inlet 3 and the outlet 4 is greatly enhanced. This greatly lowers the possibility of leakage of the working fluid 2 and greatly increases the ratio of good products.

In conclusion, in comparison with the conventional structure, the present invention has the following advantages:

1. The sealability of the inlet and the outlet is greatly enhanced.

2. The possibility of leakage of the working fluid is greatly lowered.

3. The ratio of good products is greatly increased.

4. The damage of the vacuuming device is avoided.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A manufacturing method of a roll bond plate evaporator, comprising steps of:
providing a heat dissipation member having at least one inlet and at least one outlet and formed with an internal flow way in communication with the inlet and the outlet;
providing a cleaning liquid to fill into the heat dissipation member from the inlet and flow from the inlet through the flow way to the outlet and discharge out of the heat dissipation member;
providing a sealing device to seal the outlet; and
providing a vacuuming device to vacuum the flow way and filling a working fluid into the flow way from the inlet and then sealing the inlet.

2. The manufacturing method of the roll bond plate evaporator as claimed in claim 1, further comprising a step of providing a drying device to dry the flow way after the step of providing a cleaning liquid to fill into the heat dissipation member from the inlet and flow from the inlet through the flow way to the outlet and discharge out of the heat dissipation member.

3. The manufacturing method of the roll bond plate evaporator as claimed in claim 1, further comprising a step of providing a liquid to fill from the inlet into the heat dissipation member so as to wash out the cleaning liquid remaining in the flow way and flow out of the outlet to discharge from the heat dissipation member after the step of providing a cleaning liquid to fill into the heat dissipation member from the inlet and flow from the inlet through the flow way to the outlet and discharge out of the heat dissipation member.

4. The manufacturing method of the roll bond plate evaporator as claimed in claim 3, further comprising a step of providing a drying device to dry the flow way after the step of providing a liquid to fill from the inlet into the heat dissipation member so as to wash out the cleaning liquid remaining in the flow way and flow out of the outlet to discharge from the heat dissipation member.

5. The manufacturing method of the roll bond plate evaporator as claimed in claim 1, wherein the cleaning liquid is a chemical agent.

6. The manufacturing method of the roll bond plate evaporator as claimed in claim 3, wherein the liquid is pure water.

7. The manufacturing method of the roll bond plate evaporator as claimed in claim 1, wherein the sealing device is a welding device, the outlet being sealed by the welding device by means of argon arc welding, flame welding, high-frequency welding or laser welding.

8. The manufacturing method of the roll bond plate evaporator as claimed in claim 1, wherein the heat dissipation member is composed of a first plate body and a second plate body, which are correspondingly mated with each other by means of welding, the first and second plate bodies together defining the flow way.
